(19) United States
(12) Patent Application Publication
(10) Pub. No.: US 2024/0192309 A1
(43) Pub. Date: Jun. 13, 2024

(54) APPARATUS FOR PROCESSING INTERFERENCE SIGNAL OF AUTOMOTIVE RADER AND RECORDING MEDIUM STORING INSTRUCTION TO PERFORM METHOD FOR PROCESSING INTERFERENCE SIGNAL OF AUTOMOTIVE RADER

(71) Applicant: Research & Business Foundation SUNGKYUNKWAN UNIVERSITY, Suwon-si (KR)

(72) Inventors: Byung Sung KIM, Suwon-si (KR); Reem SONG, Suwon-si (KR); Mingeon SHIN, Suwon-si (KR)

(73) Assignee: Research & Business Foundation SUNGKYUNKWAN UNIVERSITY, Suwon-si (KR)

(21) Appl. No.: 18/142,775

(22) Filed: May 3, 2023

(30) Foreign Application Priority Data
May 3, 2022 (KR) 10-2022-0054931

(51) Int. Cl. G01S 7/02; G01S 13/931

(52) U.S. Cl. CPC G01S 7/023; G01S 13/931

(57) ABSTRACT

The present disclosure relates to an apparatus and method for processing interference signal of an automotive radar, and more particularly, to an apparatus and method for processing interference signal of an automotive radar to detect and cancel interference signal of the automotive radar.

### TECHNICAL FIELD

The present disclosure relates to a device and method for processing an automotive radar interference signal, and more particularly, to a device and method for processing an automotive radar interference signal to detect and cancel interference signal of the automotive radar.

This work was supported by Institute of Information & communications Technology Planning & Evaluation (IITP) grant funded by Korea government (MSIT) [(No. 20009868, Next Generation Intelligent Semiconductor Technology Development (Design and Manufacturing) Project).

### BACKGROUND

With widespread commercialization of automotive radars, problems due to mutual interference between radars may occur.

Interference signals may cause information errors in distances or speeds in target detection and lead to false target recognition or failure to detect real targets, and thus can become a significant issue when vehicle radar installation further expands in the future.

Current commercial forward-facing radars for vehicles use frequency modulated continuous wave (FMCW) signals, and interference appears in the form of impulses in the time domain and appears as a broadband interference noise spectrum in an intermediate frequency (IF). Therefore, these signals are indistinguishable in the frequency domain and readable in the time domain.

Forward-facing radars for vehicles have a high signal strength, and thus a radar of a vehicle can detect a radar signal of an oncoming vehicle or a vehicle approaching from the side. The currently commercialized forward-facing radars for vehicles use FMCW signals and use fast chirps that are resistant to interference for frequency modulation. Interference caused by synchronization of radars of the same or different types is practically impossible.

When an interference signal is generated, it might be a problem for an interference signal having a signal strength equal to or greater than a certain level to enter into a reception frequency band even if a chirp timing and signal waveform are different. Interferences with different chirp slopes appear as a broadband interference noise spectrum at an IF. This may lead to target detection failure due to a decrease in a signal-to ratio (SNR). In particular, in the case of a next-generation high-resolution radar for autonomous driving, an SNR decrease causes a problem of decrease in angular resolution.

Since current interference detection technology uses only a signal processing technique to determine presence or absence of interference depending on whether or not an IF signal reaches a specific threshold value, this method cannot detect interference below the threshold value and requires complicated signal processing and algorithm in determining an appropriate threshold value. In addition, this method causes loss and distortion of a part of a target signal, which leads to a decrease in a target detection rate.

### SUMMARY

The present disclosure has been proposed to solve the above problems, and an object of the present disclosure is to provide an automotive radar interference signal processing device and method for detecting and canceling interference signals of other vehicles or other devices applied to an automotive radar.

Problems to be solved by the present invention are not limited to those mentioned above, and other problems to be solved that are not mentioned will be clearly understood by those skilled in the art from the description below.

In accordance with an aspect of the present disclosure, there is provided an apparatus for processing interference signal of automotive radar, the apparatus comprises: a signal receiver including a main receiver for receiving an external signal in order to detect a target signal and a sub-receiver for detecting an interference signal with respect to the target signal; a first filter configured to detect a first received signal from the external signal received from the main receiver; a second filter configured to detect a second received signal from the interference signal received from the sub-receiver; and a processor configured to process the first and second received signals detected through the first and second filters, wherein the processor is configured to obtain a target signal from which the interference signal has been canceled by subtracting the second received signal from the first received signal.

The signal receiver may include one shared antenna, the main receiver may include a main mixer for changing a frequency of the external signal received through the shared antenna, and the sub-receiver may be connected to the shared antenna and include an additional mixer having a second frequency obtained by adding a positive frequency offset to a first frequency of the main mixer.

The positive frequency offset added to the additive mixer may be set to be greater than a filter bandwidth through which signals generated in the sub-receiver and the main receiver pass such that only the interference signal is detected in the additional mixer when the target signal and the interference signal are applied.

The first filter may be connected to the main mixer and filters the external signal in accordance with a preset bandwidth, and the second filter may be connected to the additional mixer and filters the interference signal received from the additional mixer in accordance with a preset bandwidth.

The processor may be configured to shift the interference signal on a time axis based on the time of the external signal on the basis of a time difference between the external signal and the interference signal.

The signal receiver may include a first antenna configured to receive the external signal and connected to the main receiver; and a second antenna configured to receive the external signal independently of the first antenna and connected to the sub-receiver.

The main receiver may include a main mixer for converting a frequency of the external signal transmitted from the first antenna, and the sub-receiver may include an additional mixer configured to convert a frequency of the external signal transmitted from the second antenna into a second frequency obtained by adding a positive frequency offset to a first frequency of the main mixer.

The positive frequency offset added to the additional mixer may be set to be greater than a filter bandwidth through which signals generated in the sub-receiver and the main receiver pass such that only the interference signal is detected in the additional mixer when the target signal and the interference signal are applied. The processor may be configured to correct a phase difference between the external signal and the interference signal on the basis of the external signal, and shift the interference signal on the time axis based on the time of the external signal on the basis of the time difference between the external signal and the interference signal.

The apparatus may comprise first and second analog-digital converters (ADCs) configured to convert analog signals output from the first and second filters into digital signals, and the processor may be configured to process the digital signals output through the first and second ADCs.

The processor may be configured to check phase information with Hilbert transform of a real signal, correct a phase difference between the external signal and the interference signal on the basis of the external signal, calculate a phase difference between the main receiver and the sub-receiver on the basis of the Hilbert transform, recover a signal of the sub-receiver using the phase difference, calculate a time shift between the external signal and the interference signal, shift ADC samples by the time shift, and subtract the interference signal from the external signal.

In accordance with another aspect of the present disclosure, there is provided an apparatus for processing interference signal of automotive radar, the apparatus comprises: a signal receiver including first and second antennas, first and second antenna switches respectively connected to the first and second antennas, and a first processor configured to control the first and second antenna switches according to a result of determination based on predetermined conditions with respect to a state of a automotive radar, and configured to detect an external signal and an interference signal with respect to a target signal in order to detect the target signal from RF signals received from the first and second antennas; a first filter configured to detect a first received signal from the external signal; a second filter configured to detect a second received signal from the interference signal; and a second processor configured to process the first and second received signals, wherein the second processor obtains a target signal from which the interference signal has been canceled by subtracting the second received signal from the first received signal, and the signal receiving unit is connected only to the first antenna to detect the external signal and the interference signal from a signal received from the first antenna or connected to both the first and second antennas to detect the external signal and the interference signal from signals received from the first and second antennas by the first processor controlling the first and second antenna switches.

The signal receiver may include a main receiver directly connected to the first antenna and including a main mixer configured to convert a frequency of the external signal received through the first antenna; and a sub-receiver connected to the second antenna through the second antenna switch and including an additional mixer having a second frequency obtained by adding a positive frequency offset to a first frequency of the main mixer, wherein the first antenna switch may be branched from a path connecting the first antenna and the main mixer and connected to the additional mixer, and connection between the first antenna and the additional mixer may be controlled by a control signal provided by the first processor.

The first filter may be connected to the main mixer and filters the received signal in accordance with a preset bandwidth, the second filter may be connected to the additional mixer and filters the interference signal received from the additional mixer in accordance with a preset bandwidth, the second processor may be configured to correct a phase difference between the interference signals of the sub-receiver and the main receiver, and shift the interference signal of the sub-receiver on a time axis on the basis of a time difference between the interference signals of the sub-receiver and the main receiver, and the first processor may be configured to provide information for controlling whether or not to correct a phase difference to the second processor, and the second processor may be configured to process phase difference correction on the basis of the information for controlling whether or not to correct a phase difference.

The first processor may be configured to control the antenna switches such that the main receiver and the sub-receiver share the first antenna and provide control information for not allowing the phase difference correction to the second processor upon determining that the second antenna does not normally operate.

In accordance with another aspect of the present disclosure, there is provided a non-transitory computer-readable storage medium storing a computer program, which comprises instructions for a processor to perform a method, the method comprise: receiving an external signal through a main receiver in order to detect a target signal and receiving an external signal through a sub-receiver in order to detect an interference signal with respect to the target signal in an automotive radar device in which the main receiver and the sub-receiver are connected to at least one antenna; obtaining a first received signal by applying a filter to the external signal received from the main receiver; obtaining a second received signal by correcting the interference signal received from the sub-receiver; and obtaining a target signal from which the interference signal has been canceled by subtracting the second received signal from the first received signal

The obtaining of the second received signal may include shifting the interference signal on a time axis on the basis of a time difference between the external signal and the interference signal.

The obtaining of the second received signal may further comprise correcting a phase difference between the external signal and the interference signal.

The correcting of the phase difference between the external signal and the interference signal may include checking phase information of the external signal and the interference signal with Hilbert transform of a real signal for each of the external signal and the interference signal and correcting the phase difference between the external signal and the interference signal.

According to the apparatus and method for processing interference signal of the automotive radar according to an embodiment of the present disclosure, interference signals of other vehicles or other devices applied to an automotive radar can be detected and canceled.

In addition, according to the apparatus and method for processing interference signal of the automotive radar according to an embodiment of the present disclosure, only an interference signal can be effectively separated, detected, and canceled, and thus only a target signal from which the interference signal has been excluded can be derived to improve a target detection rate of the radar.

Effects of the present invention are not limited to those mentioned above, and other effects that are not mentioned will be clearly understood by those skilled in the art from the description below.

### BRIEF DESCRIPTION OF THE DRAWINGS

FIG. 1 is a block diagram illustrating a configuration of an apparatus for processing interference signal of an automotive radar according to a first embodiment of the present disclosure.

FIG. 2 is a block diagram illustrating a configuration of an apparatus for processing interference signal of an automotive radar according to a second embodiment of the present disclosure.

FIG. 3 is a signal graph for describing a relationship between LOs and interference signals of a main receiver and a sub-receiver.

FIG. 4 is a diagram illustrating a hardware configuration of the apparatus for processing interference signal of the automotive radar shown in FIGS. 1 and 2.

FIG. 5 is an algorithm block diagram for describing a phase correction process according to an embodiment of the present disclosure.

FIG. 6 is a block diagram illustrating a configuration of an apparatus for processing interference signal of an automotive radar according to a third embodiment of the present disclosure.

FIG. 7 is a flowchart illustrating a method for processing interference signal of an automotive radar according to the first embodiment of the present disclosure.

FIG. 8 is a flowchart illustrating a method for processing interference signal of an automotive radar according to the second embodiment of the present disclosure.

FIG. 9 is a flowchart illustrating a method for processing interference signal of an automotive radar according to the third embodiment of the present disclosure.

FIG. 10 illustrates an example of simulation by an apparatus for processing interference signal of an automotive radar according to an embodiment of the present disclosure.

### DETAILED DESCRIPTION

The advantages and features of the embodiments and the methods of accomplishing the embodiments will be clearly understood from the following description taken in conjunction with the accompanying drawings. However, embodiments are not limited to those embodiments described, as embodiments may be implemented in various forms. It should be noted that the present embodiments are provided to make a full disclosure and also to allow those skilled in the art to know the full range of the embodiments. Therefore, the embodiments are to be defined only by the scope of the appended claims.

Terms used in the present specification will be briefly described, and the present disclosure will be described in detail.

In terms used in the present disclosure, general terms currently as widely used as possible while considering functions in the present disclosure are used. However, the terms may vary according to the intention or precedent of a technician working in the field, the emergence of new technologies, and the like. In addition, in certain cases, there are terms arbitrarily selected by the applicant, and in this case, the meaning of the terms will be described in detail in the description of the corresponding invention. Therefore, the terms used in the present disclosure should be defined based on the meaning of the terms and the overall contents of the present disclosure, not just the name of the terms.

When it is described that a part in the overall specification “includes” a certain component, this means that other components may be further included instead of excluding other components unless specifically stated to the contrary.

Hereinafter, preferred embodiments of the present disclosure will be described in more detail with reference to the accompanying drawings.

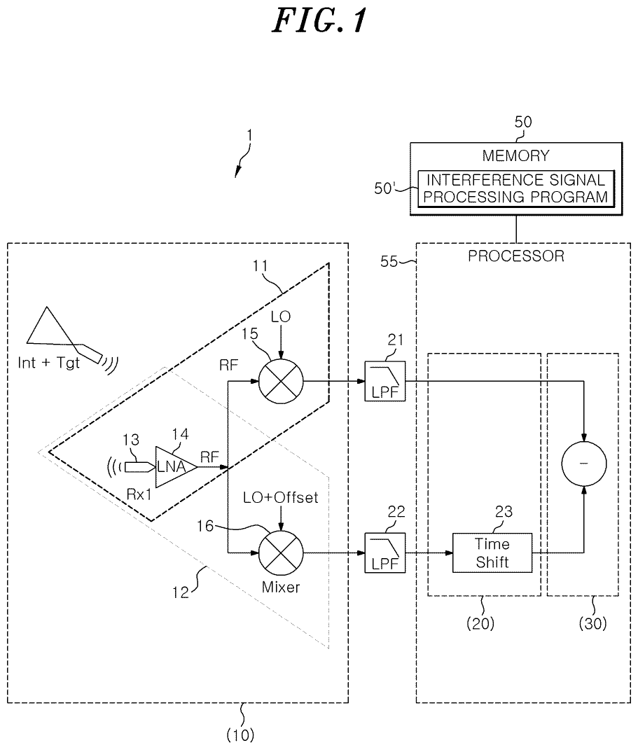

FIG. 1 is a block diagram illustrating a configuration of an apparatus for processing interference signal of an automotive radar according to a first embodiment of the present disclosure.

Referring to FIG. 1, the apparatus for processing interference signal of the automotive radar according to the first embodiment of the present disclosure may include a signal receiver 10, a first filter 21, a second filter 22, a signal processor 20, and a target signal acquisition unit 30. In FIG. 1, Int+Tgt denotes an interference signal and a target signal applied to a main receiver 11 and a sub-receiver 12.

A plurality of filters may be provided in various embodiments of the present disclosure, and in order to distinguish filters provided in apparatus for processing interference signal of automotive radar of respective embodiments, the first filter 21 and the second filter 22 provided in the apparatus for processing interference signal of automotive radar 1 according to the first embodiment of the present disclosure may be referred to as a (1-1)-th filter 21 and a (1-2)-th filter 22.

The signal receiver 10 may include the main receiver 11 for receiving an external signal to detect a target signal and the sub-receiver 12 for detecting an interference signal with respect to the target signal.

Here, the main receiver 11 and the sub-receiver 12 are connected to one shared antenna 13. A signal applied to the shared antenna 13 may be amplified through a low-noise amplifier (LNA).

The main receiver 11 is connected to a main mixer 15 for changing the frequency of the external signal, and the sub-receiver 12 includes an additional mixer 16 having a local oscillator (LO) frequency obtained by adding a positive frequency offset to an LO frequency of the main mixer 15.

Here, the positive frequency offset added to the additional mixer 16 may be set within a predetermined range. In one embodiment, the offset may be set to be greater than a filter bandwidth through which signals generated by the sub-receiver 12 and the main receiver 11 pass such that only an interference signal is detected in the sub-receiver 12 when a target signal and the interference signal are applied.

The main receiver 11 and the sub-receiver 12 have the same frequency modulated continuous wave (FMCW) characteristics, but the LO of the sub-receiver 12 is designed to have a positive offset with respect to the LO frequency of the main receiver 11. After the interference signal passes through the low pass filter (LPF) of each receiver, the interference signal of the sub-receiver 12 is subtracted from the signal that has passed through the main receiver 11 through time shift.

The apparatus for processing interference signal of the automotive radar 1 may obtain a first received signal by applying a filter to the external signal received from the main receiver 11 and obtain a second received signal by correcting the interference signal received from the sub-receiver 12. As described above, multiple signals can be received in various embodiments of the present disclosure, and in order to distinguish signals received in the respective embodiments, the first received signal and the second received signal received by the apparatus for processing interference signal of the automotive radar 1 according to the first embodiment of the present disclosure may be referred to as a (1-1)-th received signal and a (1-2)-th received signal.

To this end, the apparatus for processing interference signal of the automotive radar 1 includes the (1-1)-th filter 21 and the (1-2)-th filter 22.

The (1-1)-th filter 21 may be connected to the main mixer 15 and output the (1-1)-th received signal by filtering the external signal in accordance with a preset bandwidth. In one embodiment, the (1-1)-th filter 21 may be provided as a low pass filter (LPF).

The (1-2)-th filter 22 may be connected to the additional mixer 16 and output the (1-2)-th received signal by filtering the interference signal received from the additional mixer 16 in accordance with a preset bandwidth. In one embodiment, the (1-2)-th filter 22 may be provided as a low pass filter (LPF).

The signal processor 20 may include a time shifter 23. Here, the time shifter 23 may shift the interference signal of the sub-receiver 12 on the time axis on the basis of the time difference between the interference signals of the sub-receiver 12 and the main receiver 11.

The target signal acquisition unit 30 may obtain a target signal from which the interference signal has been canceled by subtracting the (1-2)-th received signal from the (1-1)-th received signal.

As described above, in the first embodiment, the main receiver 11 and the sub-receiver 12 share the antenna 13 in hardware for interference signal processing, one receiver (main receiver 11) includes two mixers 15 and 16, and a signal is subtracted through only the time shifter 23.

Furthermore, the apparatus for processing interference signal of the automotive radar 1 according to the first embodiment of the present disclosure may include a memory 50 and a processor 55.

The memory 50 may store an interference signal processing program 50′ and information necessary to execute the interference signal processing program 50′.

In one embodiment of the present disclosure, the interference signal processing program 50′ may refer to software including instructions programmed to process an automotive radar interference signal processing method. In particular, the interference signal processing program 50′ may include instructions for executing the functions of the signal processor 20 and the target signal acquisition unit 30 described above.

The processor 55 may overall control the operation of the apparatus for processing interference signal of automotive radar.

The processor 55 may load the interference signal processing program 50′ and the information necessary to execute the interference signal processing program 50′ from the memory 50 in order to execute the interference signal processing program 50′.

In particular, the processor 55 may process the functions of the above-described signal processor 20 and target signal acquisition unit 30 by executing the interference signal processing program 50′. For example, the processor 55 may check a time difference between the (1-1)-th received signal and the (1-2)-th received signal and control the timing of the (1-1)-th received signal or the (1-2)-th received signal. Further, the processor 55 may obtain a target signal from which the interference signal has been canceled by subtracting the (1-2)-th received signal from the (1-1)-th received signal.

Hereinafter, an apparatus for processing interference signal of an automotive radar according to a second embodiment of the present disclosure will be described.

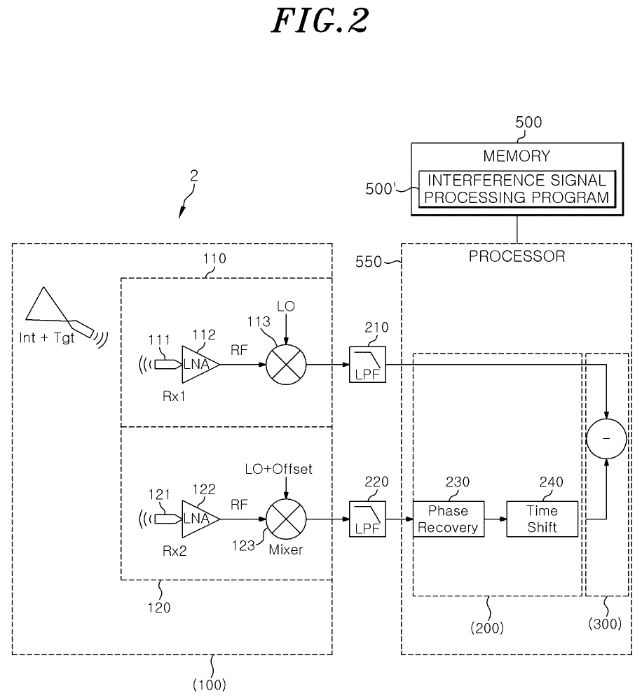

FIG. 2 is a block diagram illustrating a configuration of the apparatus for processing interference signal of the automotive radar according to the second embodiment of the present disclosure.

Referring to FIG. 2, the apparatus for processing interference signal of the automotive radar 2 according to the second embodiment of the present disclosure may include a signal receiver 100, a first filter 210, a second filter 220, a signal processor 200, and a target signal acquisition unit 300. In FIG. 2, Int+Tgt denotes an interference signal and a target signal applied to a main receiver 110 and a sub-receiver 120. As described above, the first filter 210 and the second filter 220 provided in the apparatus for processing interference signal of the automotive radar 2 according to the second embodiment of the present disclosure may be referred to as a (2-1)-th filter 210 and a (2-2)-th filter 220.

The signal receiver 100 may include the main receiver 110 (RX1) for receiving an external signal to detect a target signal and a sub-receiver 120 (RX2) for detecting an interference signal with respect to the target signal.

The main receiver 110 and the sub-receiver 120 are independently connected to the respective antennas 111 and 121.

The main receiver 110 includes a first antenna 111 for receiving the external signal and a main mixer 113 connected to the first antenna 111 to convert the frequency of the external signal.

The sub-receiver 120 may include the second antenna 121 for receiving the external signal independently of the first antenna 111, and an additional mixer 123 connected to the second antenna 121 and having an LO frequency obtained by adding a positive frequency offset to an LO frequency of the main mixer 113. In the second embodiment, the sub-receiver 120 is the same as the sub-receiver RX2.

Here, the positive frequency offset added to the additional mixer 123 may be set within a predetermined range. In one embodiment, the offset may be set to be greater than a filter bandwidth through which signals generated by the sub-receiver 120 and the main receiver 110 pass such that only an interference signal is detected in the additional mixer 123 when a target signal and the interference signal are applied.

The main receiver 110 and the sub-receiver 120 have the same frequency modulated continuous wave (FMCW) characteristics, but the LO of the sub-receiver 120 is designed to have a positive offset with respect to the LO frequency of the main receiver 110. After the interference signal passes through a low pass filter (LPF) of each receiver, the interference signal of the sub-receiver 120 is subtracted from the signal that has passed through the main receiver 110 through phase correction and time shift.

The apparatus for processing interference signal of the automotive radar 2 includes the (2-1)-th filter 210 and the (2-2)-th filter 220.

The (2-1)-th filter 210 may be connected to the main mixer 113 and output a first received signal by filtering the received signal in accordance with a preset bandwidth. In one embodiment, the (2-1)-th filter 210 may be provided as a low pass filter (LPF).

The (2-2)-th filter 220 may be connected to the additional mixer 123 and output a second received signal by filtering the interference signal received from the additional mixer 123 in accordance with a preset bandwidth. In one embodiment, the (2-2)-th filter 220 may be provided as a low pass filter (LPF).

The signal processor 200 may include a phase corrector 230 and a time shifter 240. The phase corrector 230 may correct a phase difference between the interference signals of the sub-receiver 120 and the main receiver 110. In addition, the time shifter 240 may shift the interference signal of the sub-receiver 120 on the time axis on the basis of a time difference between the interference signals of the sub-receiver 120 and the main receiver 110.

The target signal acquisition unit 300 may obtain a target signal from which the interference signal has been canceled by subtracting the second received signal from the first received signal. As described above, multiple signals may be received in various embodiments of the present disclosure, and in order to distinguish signals received in the respective embodiments, the first received signal and the second received signal received in the apparatus for processing interference signal of the automotive radar 2 according to the second embodiment of the present disclosure may be referred to as a (2-1)-th received signal and a (2-2)-th received signal.

Furthermore, the apparatus for processing interference signal of the automotive radar 2 according to the second embodiment of the present disclosure may include a memory 500 and a processor 550.

The memory 500 may store an interference signal processing program 500′ and information necessary to execute the interference signal processing program 500′.

In one embodiment of the present disclosure, the interference signal processing program 500′ may refer to software including instructions programmed to process a method for processing interference signal of an automotive radar. In particular, the interference signal processing program 500′ may include instructions for executing the functions of the signal processor 220 and the target signal acquisition unit 300 described above.

The processor 550 may overall control the operation of the apparatus for processing interference signal of the automotive radar.

The processor 550 may load the interference signal processing program 500′ and the information necessary to execute the interference signal processing program 500′ from the memory 500 in order to execute the interference signal processing program 500′.

In particular, the processor 550 may process the functions of the above-described signal processor 200 and target signal acquisition unit 300 by executing the interference signal processing program 500′. For example, the processor 550 may check a phase difference between the (2-1)-th received signal and the (2-2)-th received signal and control the phase of the (2-1)-th received signal or the (2-2)-th received signal or check the time difference between the (2-1)-th received signal and the (2-2)-th received signal and control the timing of the (2-1)-th received signal or the (2-2)-th received signal. Further, the processor 550 may obtain a target signal from which the interference signal has been canceled by subtracting the (2-2)-th received signal from the (2-1)-th received signal.

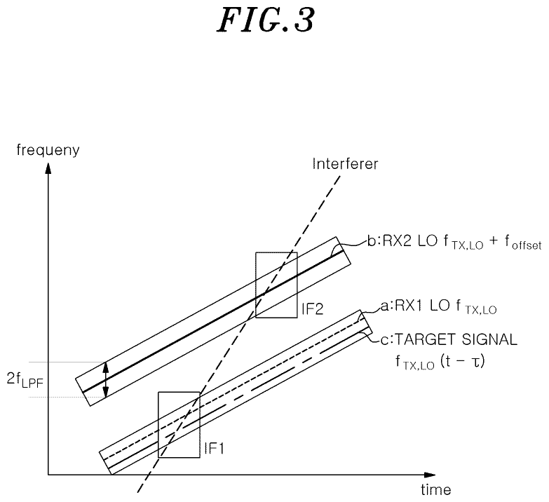

FIG. 3 is a signal graph for describing a relationship between LOs and interference signals of a main receiver and a sub-receiver.

Referring to FIG. 3, it can be ascertained that, when an interference signal (dotted line, interferer) is input to RX1 LO (a) and RX2 LO (b) having an FMCW waveform, intersections occur with a time difference.

As to an IF signal down-converted by being mixed with each LO, both a target signal (c) and an interference signal are present within an LPF bandwidth in the case of signal waveforms of RX1 (area IF1), and a signal waveform of RX2 is generated with a time difference from the interference signal of RX1 (area IF2).

Since the target signal input to RX2 is within an LPF cutoff range, only the interference signal is present in the final stage of RX2.

Accordingly, as shown in FIGS. 1 and 2, the signal of RX2 that has been subjected to time shift completely overlaps the interference signal of RX1. However, if the phases do not match, it is assumed that the phase of the signal of RX2 has been corrected. Therefore, if the interference signal of RX2 that has been subjected to the time shift is subtracted from the signal of RX1, a signal from which only the interference signal has been canceled is output from the main receiver.

If the interference signal is subjected to frequency modulation with a slope less than the linear frequency modulation slope of the LOs of the main receiver and sub-receiver, two intersections also occur, but in this case, IF occurs first in RX2. Therefore, if the IF signal of RX2 is delayed and subtracted from the IF signal of RX1 in the signal processing stage, the interference signal can be removed in the same manner.

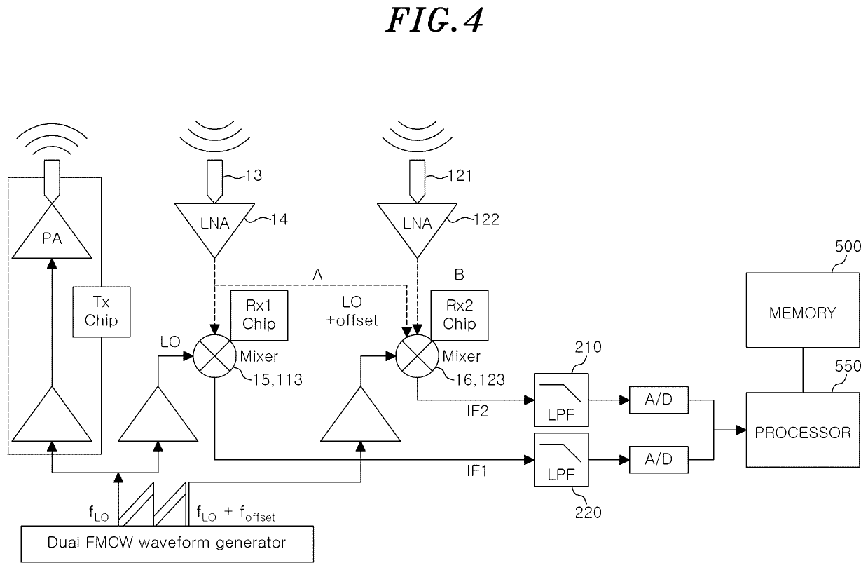

FIG. 4 is a diagram illustrating a hardware configuration of the apparatus for processing interference signal of the automotive radar shown in FIGS. 1 and 2.

A receiver having a separate antenna 121 and LNA 122 is added if the sub-receiver 120 of FIG. 2 is added, and the antenna 13 and the LNA 14 are shared if the additional mixer 16 of FIG. 1 is added.

Referring to FIG. 4, a signal that has passed through an LPF is processed in the processor 550 after passing through an analog-digital converter (ADC). Phase recovery (230) and time shift signal processing (240) of FIG. 2 are implemented in this block. The processor 550 may perform Hilbert transform on a real signal to obtain phase information and perform correction. Although, in one embodiment of the present disclosure, the processor 550 processes phase correction, the present disclosure is not limited thereto, and the apparatus for processing interference signal of the automotive radar may include an IQ mixer configured as hardware and perform phase correction using the IQ mixer.

The process of obtaining and correcting phase information using an IQ mixer when an arbitrary phase difference occurs in the sub-receiver RX2 can be verified by formulas. In conclusion, the IQ channel IF signal of RX2 is not the same as the signal of RX1 and is generated in the form of a signal obtained by rotating the IQ signal of RX1 by an added arbitrary phase difference. Therefore, if the IQ signal of RX2 is rotated inversely, it matches the interference signal of RX1, and thus the interference signal can be canceled.

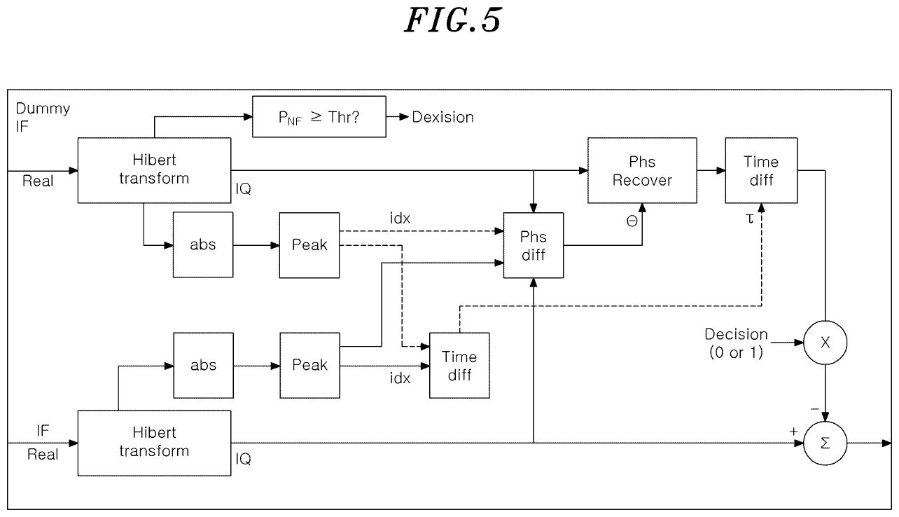

FIG. 5 is an algorithm block diagram for describing a phase correction process according to an embodiment of the present disclosure.

Referring to FIG. 5, the processor 550 may perform phase correction operation illustrated in FIG. 5 by executing the interference signal processing program 500′. For example, as an embodiment for performing phase correction, the processor 550 may perform phase correction by Hilbert transforming a real signal and execute a signal processing process of canceling an interference signal.

This process may include the following three steps.

That is, the process may include a step of calculating a phase difference between the main receiver 110 and the sub-receiver 120, a step of restoring the signal of the sub-receiver 120 using the calculated phase difference, and a step of calculating a time shift between signals of the main receiver 110 and the sub-receiver 120, shifting an ADC sample by this shift with respect to the signal of the sub-receiver 120, and subtracting the same from the signal of the main receiver 110.

As described above, since the IF signal of the sub-receiver 120 has only the interference signal after passing through the LPF, the phase of the interference signal can be regarded as an instantaneous phase of a signal having a maximum amplitude. A phase difference is extracted from the phases of maximum signal waveforms of the main receiver 110 and the sub-receiver 120, and a phase-corrected signal waveform of the signal of the sub-receiver 120 is obtained using the phase difference.

The number of ADC samples to be shifted is obtained through the following process.

If the duration of interference within the IF bandwidth of the sub-receiver 120 is ascertained, the slope of the interference signal can be obtained by Equation 1 below.

sᵢ=2f_{off}/tᵢ [Equation 1]

From this, a required time shift can be calculated as represented by Equation 2. Here, for is a frequency offset and sᵢ is a frequency modulation slope of the interference signal over time.

Δτ=f_{off}/(sᵢ−sₒ) [Equation 2]

When the interference signal exhibits falling frequency modulation over time, interference first occurs in the sub-receiver 120 instead of the main receiver 110. In this case, Equations 1 and 2 can be equally applied. Here, sᵢ and sₒ are frequency modulation slopes of the interference signal and the main receiver (or sub-receiver) FMCW signal over time, respectively.

Hereinafter, an apparatus for processing interference signal of an automotive radar according to a third embodiment of the present disclosure will be described.

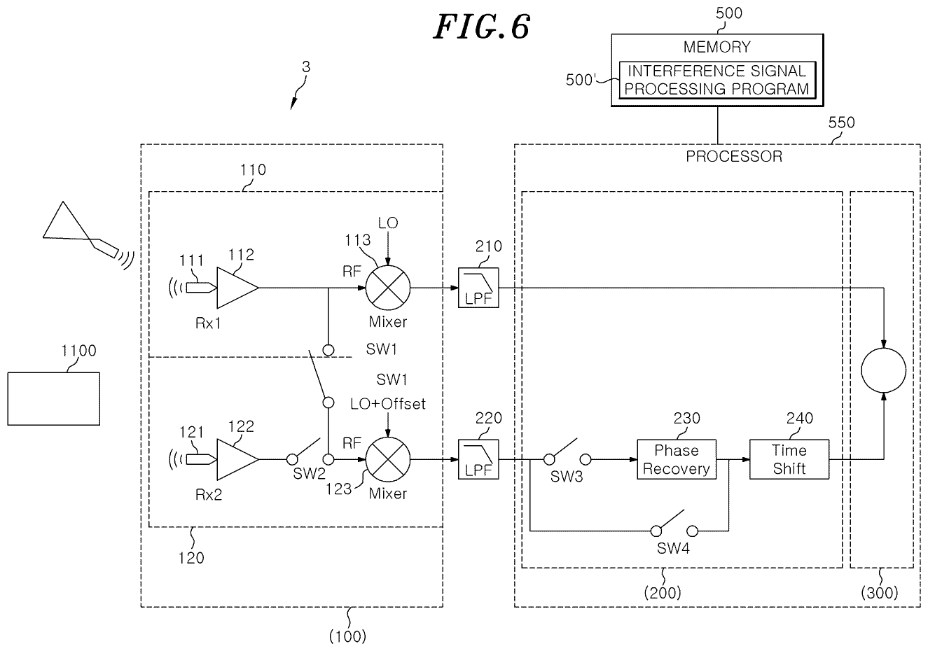

FIG. 6 is a block diagram illustrating a configuration of the apparatus for processing interference signal of the automotive radar according to the third embodiment of the present disclosure.

Referring to FIG. 6, the apparatus for processing interference signal of the automotive radar 3 according to the third embodiment includes all components of the apparatus for processing interference signal of the automotive radar 2 according to the second embodiment, and differs from the apparatus for processing interference signal of the automotive radar 2 according to the second embodiment in that the former additionally includes switches SW1 to SW4 and a switch controller 1100.

The apparatus for processing interference signal of the automotive radar according to the third embodiment may implement the apparatus for processing interference signal of the automotive radar of the first embodiment (1) or the second embodiment (2) according to at least one of a state of an automotive radar, a vehicle state, and a vehicle external environment condition by including at least one switch and a switch controller, thereby implementing an apparatus for processing interference signal of the automotive radar in a transformer type.

In an embodiment, the apparatus for processing interference signal of the automotive radar 3 according to the third embodiment is basically configured the same as the apparatus for processing interference signal of the automotive radar 2 according to the second embodiment shown in FIG. 2 and further includes the first switch SW1, the second switch SW2, the third switch SW3, the fourth switch SW4, and the switch controller 1100.

The switch controller 1100 determines switching signals for the first to fourth switches SW1 to SW4 according to a result of determination based on a predetermined condition with respect to at least one of a state of the automotive radar, a vehicle state, and a vehicle external environment.

The first switch SW1 may be connected between a point branching off from a path connecting a first LNA 112 and the main mixer 113 and an additional mixer 123, the second switch SW2 may be connected between a second LNA 122 and the additional mixer 123, the third switch SW3 may be connected between a fourth LPF 220 and the phase corrector 230, and the fourth switch SW4 may be connected between a point branching off from a path connecting the fourth LPF 220 and the third switch SW3 and the time shifter 240.

The first switch SW1 and the second switch SW2 may switch sharing of one antenna 111 between the main receiver 110 and the sub-receiver 120 according to the switch controller 1100.

That is, when the first switch SW1 is turned off and the second switch SW2 is turned on, the main receiver 110 can be connected to the first antenna 111 and the sub-receiver 120 can be connected to the second antenna 121. At this time, the third switch SW3 is turned on and the fourth switch SW4 is turned off and thus the phase corrector 230 can be connected to the signal processor 200. According to such switching, an apparatus for processing interference signal of the automotive radar having the same configuration as that of the second embodiment (2) can be implemented.

On the other hand, when the first switch SW1 is turned on and the second switch SW2 is turned off, the main receiver 110 and the sub-receiver 120 can share the first antenna 111.

At this time, the third switch SW3 is turned off and the fourth switch SW4 is turned on and thus the phase corrector 230 is excluded from the signal processor 200. According to such switching, an apparatus for processing interference signal of the automotive radar having the same configuration as that of the first embodiment (1) can be implemented.

In an embodiment, upon determining that the second antenna 121 does not normally operate, the switch controller 1100 may control the antenna switches SW1 and SW2 such that the main receiver 110 and the sub-receiver 120 share the first antenna 111 and control the phase correction switches SW3 and SW4 such that the phase corrector 230 is excluded.

Furthermore, when the phase corrector 230 is provided as an IQ mixer, which is a hardware component, the phase correction switches SW3 and SW4 may be configured as hardware switches. As another example, when the processor 550 is configured to perform the phase correction operation illustrated in FIG. 5 by executing the interference signal processing program 500′, a control signal for controlling the phase correction switches SW3 and SW4 is provided to the processor 550, and the processor 550 may check the control signal for controlling the phase correction switches SW3 and SW4 and control an operation for phase correction.

Since most the recent automotive radars are based on Multi-Input Multi-Output (MIMO) technology, the influence of interference applied through various receivers inevitably increases. In a conventional technique of canceling an interference signal applied to each channel only by signal processing at an IF stage, interference detection efficiency is reduced because algorithm complexity significantly increases due to correction of a phase difference between channels.

In contrast, the present disclosure is equipped with hardware to detect and cancel interference for each channel, and thus it is more efficient to detect interference channels and cancel interference in preparation for expansion of radar multi-channels and to obtain effects of canceling interference signals and increasing a target detection rate regardless of the number of channels.

In addition, the present detection system using an FMCW radar may have an up-chirp or down-chirp modulation waveform, and is free of a linear frequency increase or decrease slope of a chirp, the bandwidth of a receiver, a chirp duration, and a chirp start timing which are chirp characteristics.

In addition, if an interference signal to be canceled is an FMCW radar signal having arbitrary linear frequency modulation, it can be detection and canceled by the apparatus for processing interference signal of the automotive radar according to the embodiments of the present disclosure.

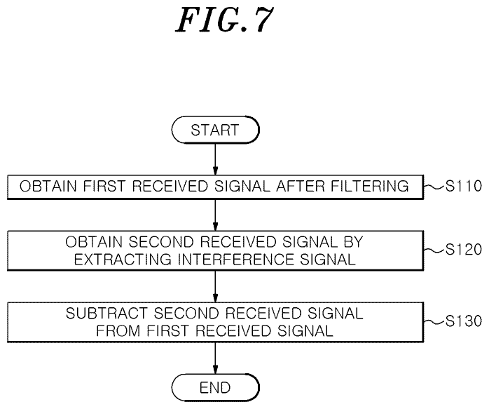

FIG. 7 is a flowchart illustrating a method for processing interference signal of an automotive radar according to the first embodiment of the present disclosure. The method for processing interference signal of the automotive radar according to the first embodiment of the present disclosure may be performed in substantially the same configuration as the apparatus for processing interference signal of the automotive radar 10 of FIG. 1. Accordingly, components identical to those of the apparatus for processing interference signal of the automotive radar 1 of FIG. 1 are denoted by the same reference numerals, and redundant description will be omitted.

Referring to FIG. 7, the method for processing interference signal of the automotive radar according to the first embodiment of the present disclosure includes step S110 of receiving an external signal through an main receiver in order to detect a target signal and receiving an external signal through a sub-receiver in order to detect an interference signal with respect to the target signal, step S120 of obtaining a (1-1)-th received signal by applying a filter to the external signal received from the main receiver, step S130 of obtaining a (1-2)-th received signal by extracting the interference signal received from the sub-receiver, and step S140 of obtaining the target signal from which the interference signal has been canceled by subtracting the (1-2)-th received signal from the (1-1)-th received signal.

Here, as shown in FIG. 1, the main receiver 11 and the sub-receiver 12 are connected to one shared antenna 13.

Here, the main receiver 11 is connected to the main mixer 15 for changing the frequency of the external signal, and the sub-receiver 12 includes the additional mixer 16 having an LO frequency obtained by adding a positive frequency offset to the LO frequency of the main mixer 15.

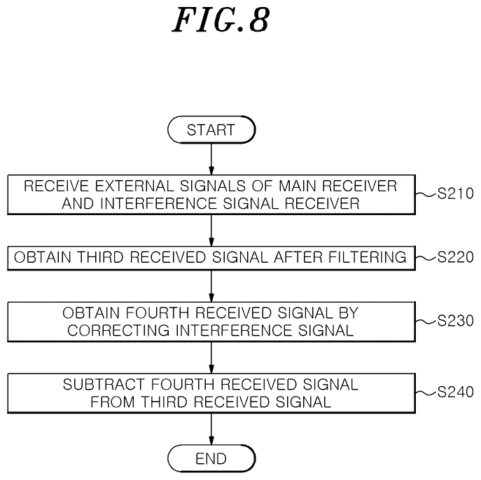

FIG. 8 is a flowchart illustrating a method for processing interference signal of an automotive radar according to the second embodiment of the present disclosure.

The method for processing interference signal of the automotive radar according to the second embodiment of the present disclosure may be performed in substantially the same configuration as the apparatus for processing interference signal of the automotive radar 2 of FIG. 2. Accordingly, components identical to those of the apparatus for processing interference signal of the automotive radar 2 of FIG. 2 are denoted by the same reference numerals, and redundant description will be omitted.

The method for processing interference signal of the automotive radar according to the second embodiment of the present disclosure includes step S210 of receiving an external signal through an main receiver in order to detect a target signal and receiving an external signal through a sub-receiver in order to detect an interference signal with respect to the target signal, step S220 of obtaining a (2-1)-th received signal by applying a filter to the external signal received from the main receiver, step S230 of obtaining a (2-2)-th received signal by correcting the interference signal received from the sub-receiver, and step S240 of obtaining the target signal from which the interference signal has been canceled by subtracting the (2-2)-th received signal from the (2-1)-th received signal.

Here, the main receiver 110 (RX1) and the sub-receiver 120 (RX2) are independently connected to the respective antennas 111 and 121.

Here, the main receiver 110 includes the first antenna 111 for receiving an external signal and the main mixer 113 connected to the first antenna 111 to convert the frequency of the external signal.

The sub-receiver 120 includes the second antenna 121 for receiving the external signal and the additional mixer 123 connected to the second antenna 121 and having an LO frequency obtained by adding a positive frequency offset to the LO frequency of the main mixer 113. Here, the sub-receiver 120 is the same as the sub-receiver RX2.

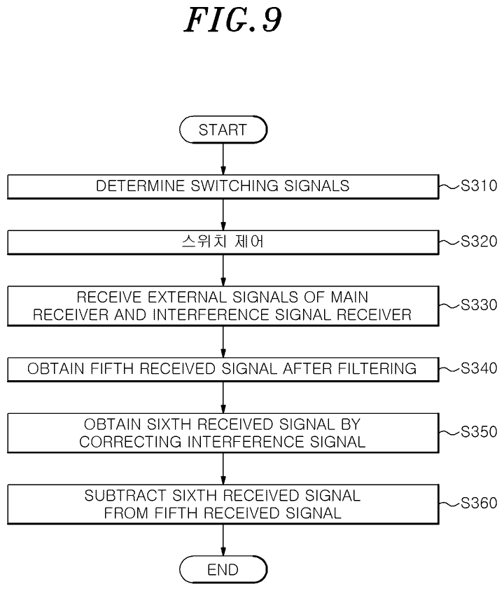

FIG. 9 is a flowchart illustrating a method for processing interference signal of an automotive radar according to the third embodiment of the present disclosure. The method for processing interference signal of the automotive radar according to the third embodiment of the present disclosure may be performed in substantially the same configuration as the apparatus for processing interference signal of the automotive radar 3 of FIG. 6. Accordingly, components identical to those of the apparatus for processing interference signal of the automotive radar 3 of FIG. 6 are denoted by the same reference numerals, and redundant description will be omitted.

The method for processing interference signal of the automotive radar according to the third embodiment of the present disclosure includes step S310 of determining, by a switch controller, switching signals for at least two switches provided in the apparatus for processing interference signal of the automotive radar according to a result of determination based on a predetermined condition with respect to at least one of a state of the automotive radar, a vehicle state, and a vehicle external environment, step S320 of controlling the switches according to the determined switching signals, step S330 of receiving an external signal through an main receiver in order to detect a target signal and receiving an external signal through a sub-receiver in order to detect an interference signal with respect to the target signal, step S340 of obtaining a (3-1)-th received signal by applying a filter to the external signal received from the main receiver, step S350 of obtaining a (3-2)-th received signal in which the interference signal has been corrected by applying a filter to the interference signal received from the sub-receiver and applying at least one of phase recovery and time shift according to the switching signals, and step S360 of obtaining the target signal from which the interference signal has been canceled by subtracting the (3-2)-th received signal from the (3-1)-th received signal.

The switch controller 1100 determines switching signals for the first to fourth switches SW1 to SW4 according to a result of determination based on a predetermined condition with respect to at least one of a state of the automotive radar, a vehicle state, and a vehicle external environment.

The main receiver 110 and the sub-receiver 120 may share one antenna or be independently connected to respective antennas by the switch controller 110 controlling the switches SW1 and SW2.

Further, the main receiver 110 includes a first antenna for receiving the external signal and a main mixer connected to the first antenna to convert the frequency of the external signal.

The sub-receiver 120 includes a second antenna for receiving the external signal independently of the first antenna and an additional mixer connected to the second antenna and having an LO frequency obtained by adding a positive frequency offset to the LO frequency of the main mixer.

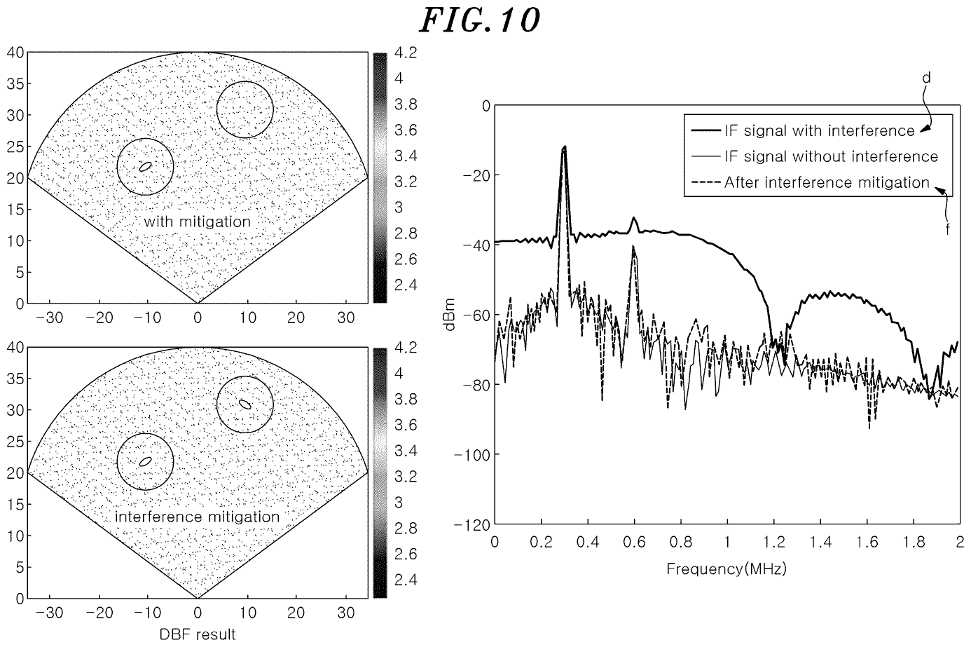

FIG. 10 illustrates an example of simulation by an apparatus for processing interference signal of automotive radar according to an embodiment of the present disclosure.

Referring to FIG. 10, when target signals as well as an interference signal are present, the target signals and the interference signal are mixed in the main receiver, and thus the second target signal may not appear clearly as can be ascertained from signal d. If the signal d passes through the apparatus for processing interference signal of the automotive radar, the interference signal is canceled and the two target signals are clearly visible as can be ascertained from signal f.

The above description is merely exemplary description of the technical scope of the present disclosure, and it will be understood by those skilled in the art that various changes and modifications can be made without departing from original characteristics of the present disclosure.

Therefore, the embodiments disclosed in the present disclosure are intended to explain, not to limit, the technical scope of the present disclosure, and the technical scope of the present disclosure is not limited by the embodiments. The protection scope of the present disclosure should be interpreted based on the following claims and it should be appreciated that all technical scopes included within a range equivalent thereto are included in the protection scope of the present disclosure.

What is claimed is:

1. An apparatus for processing interference signal of an automotive radar, the apparatus comprising:
a signal receiver including a main receiver for receiving an external signal in order to detect a target signal and a sub-receiver for detecting an interference signal with respect to the target signal;
a first filter configured to detect a first received signal from the external signal received from the main receiver;
a second filter configured to detect a second received signal from the interference signal received from the sub-receiver; and
a processor configured to process the first and second received signals detected through the first and second filters,
wherein the processor is configured to obtain a target signal from which the interference signal has been canceled by subtracting the second received signal from the first received signal.

2. The apparatus for processing interference signal of the automotive radar of claim 1, wherein the signal receiver includes one shared antenna, the main receiver includes a main mixer for changing a frequency of the external signal received through the shared antenna, and the sub-receiver is connected to the shared antenna and includes an additional mixer having a second frequency obtained by adding a positive frequency offset to a first frequency of the main mixer.

3. The apparatus for processing interference signal of the automotive radar of claim 2, wherein the positive frequency offset added to the additive mixer is set to be greater than a filter bandwidth through which signals generated in the sub-receiver and the main receiver pass such that only the interference signal is detected in the additional mixer when the target signal and the interference signal are applied.

4. The apparatus for processing interference signal of the automotive radar of claim 2, wherein the first filter is connected to the main mixer and filters the external signal in accordance with a preset bandwidth,
the second filter is connected to the additional mixer and filters the interference signal received from the additional mixer in accordance with a preset bandwidth, and
the processor is configured to shift the interference signal on a time axis based on the time of the external signal on the basis of a time difference between the external signal and the interference signal.

5. The apparatus for processing interference signal of the automotive radar of claim 1, wherein the signal receiver includes a first antenna configured to receive the external signal and connected to the main receiver; and a second antenna configured to receive the external signal independently of the first antenna and connected to the sub-receiver.

6. The apparatus for processing interference signal of the automotive radar of claim 5, wherein the main receiver includes a main mixer for converting a frequency of the external signal transmitted from the first antenna, and
the sub-receiver includes an additional mixer configured to convert a frequency of the external signal transmitted from the second antenna into a second frequency obtained by adding a positive frequency offset to a first frequency of the main mixer.

7. The apparatus for processing interference signal of the automotive radar of claim 6, wherein the positive frequency offset added to the additional mixer is set to be greater than a filter bandwidth through which signals generated in the sub-receiver and the main receiver pass such that only the interference signal is detected in the additional mixer when the target signal and the interference signal are applied.

8. The apparatus for processing interference signal of the automotive radar of claim 6, wherein the processor is configured to correct a phase difference between the external signal and the interference signal on the basis of the external signal, and shift the interference signal on the time axis based on the time of the external signal on the basis of the time difference between the external signal and the interference signal.

9. The apparatus for processing interference signal of the automotive radar of claim 4, further comprising first and second analog-digital converters (ADCs) configured to convert analog signals output from the first and second filters into digital signals,
wherein the processor processes the digital signals output through the first and second ADCs.

10. The apparatus for processing interference signal of the automotive radar of claim 8, wherein the processor configured to check phase information with Hilbert transform of a real signal, and correct a phase difference between the external signal and the interference signal on the basis of the external signal.

11. The apparatus for processing interference signal of the automotive radar of claim 10, wherein the processor calculates a phase difference between the main receiver and the sub-receiver on the basis of the Hilbert transform, recovers a signal of the sub-receiver using the phase difference, calculates a time shift between the external signal and the interference signal, shifts ADC samples by the time shift, and subtracts the interference signal from the external signal.

12. An apparatus for processing interference signal of an automotive radar, the apparatus comprising:
a signal receiver including first and second antennas, first and second antenna switches respectively connected to the first and second antennas, and a first processor configured to control the first and second antenna switches according to a result of determination based on predetermined conditions with respect to a state of an automotive radar, and configured to detect an external signal and an interference signal with respect to a target signal in order to detect the target signal from RF signals received from the first and second antennas;
a first filter configured to detect a first received signal from the external signal;
a second filter configured to detect a second received signal from the interference signal; and
a second processor configured to process the first and second received signals,
wherein the second processor is configured to obtain a target signal from which the interference signal has been canceled by subtracting the second received signal from the first received signal, and
the signal receiving unit is connected only to the first antenna to detect the external signal and the interference signal from a signal received from the first antenna or connected to both the first and second antennas to detect the external signal and the interference signal from signals received from the first and second antennas by the first processor controlling the first and second antenna switches.

13. The apparatus for processing interference signal of the automotive radar of claim 12, wherein the signal receiver includes:
a main receiver directly connected to the first antenna and including a main mixer configured to convert a frequency of the external signal received through the first antenna; and
a sub-receiver connected to the second antenna through the second antenna switch and including an additional mixer having a second frequency obtained by adding a positive frequency offset to a first frequency of the main mixer,
wherein the first antenna switch is branched from a path connecting the first antenna and the main mixer and connected to the additional mixer, and connection between the first antenna and the additional mixer is controlled by a control signal provided by the first processor.

14. The apparatus for processing interference signal of the automotive radar of claim 13, wherein the first filter is connected to the main mixer and filters the received signal in accordance with a preset bandwidth,
the second filter is connected to the additional mixer and filters the interference signal received from the additional mixer in accordance with a preset bandwidth,
the second processor is configured to correct a phase difference between the interference signals of the sub-receiver and the main receiver, and shift the interference signal of the sub-receiver on a time axis on the basis of a time difference between the interference signals of the sub-receiver and the main receiver, and
the first processor is configured to provide information for controlling whether or not to correct a phase difference to the second processor, and the second processor is configured to process phase difference correction on the basis of the information for controlling whether or not to correct a phase difference.

15. The apparatus for processing interference signal of the automotive radar of claim 14, wherein the first processor is configured to control the antenna switches such that the main receiver and the sub-receiver share the first antenna and provide control information for not allowing the phase difference correction to the second processor upon determining that the second antenna does not normally operate.

16. A non-transitory computer-readable storage medium storing a computer program, which comprises instructions for a processor to perform a method for processing interference signal of an automotive radar, the method comprising:
receiving an external signal through a main receiver in order to detect a target signal and receiving an external signal through a sub-receiver in order to detect an interference signal with respect to the target signal in an apparatus for processing interference signal of an automotive radar in which the main receiver and the sub-receiver are connected to at least one antenna;
obtaining a first received signal by applying a filter to the external signal received from the main receiver;
obtaining a second received signal by correcting the interference signal received from the sub-receiver; and
obtaining a target signal from which the interference signal has been canceled by subtracting the second received signal from the first received signal.

17. The computer-readable storage medium of claim 16, wherein the obtaining of the second received signal includes shifting the interference signal on a time axis on the basis of a time difference between the external signal and the interference signal.

18. The computer-readable storage medium of claim 16, wherein the obtaining of the second received signal further comprises correcting a phase difference between the external signal and the interference signal.

19. The computer-readable storage medium of claim 18, wherein the correcting of the phase difference between the external signal and the interference signal includes checking phase information of the external signal and the interference signal with Hilbert transform of a real signal for each of the external signal and the interference signal and correcting the phase difference between the external signal and the interference signal.
